(19) United States
(12) Patent Application Publication
(10) Pub. No.: US 2025/0007785 A1
(43) Pub. Date: Jan. 2, 2025

(54) WIRELESS DEVICE, FIRST NETWORK NODE, SECOND NETWORK NODE AND METHODS THEREIN

(71) Applicant: Telefonaktiebolaget LM Ericsson (publ), Stockholm (SE)

(72) Inventors: Ananya MUDDUKRISHNA, Enskededalen (SE); Dhruvin PATEL, Aachen (DE); Yufei BLANKENSHIP, Kildeer, IL (US); Fedor CHERNOGOROV, Espoo Uusimaa (FI)

(21) Appl. No.: 18/292,091

(22) PCT Filed: Jul. 28, 2021
(86) PCT No.: PCT/SE2021/050758

§ 371 Date: Jan. 25, 2024

(51) Int. Cl. H04L 41/14; H04L 41/122

(52) U.S. Cl. CPC H04L 41/145; H04L 41/122

(57) ABSTRACT

A method performed by a first network node for handling communication of data in a wireless communications network is provided. The first network node manages a virtual communication model. The virtual communication model simulates a communication of a set of data streams between a wireless device and a second network node. The first network node receives a relationship indication from the second network node. The relationship indication indicates at least one relationship between one or more first data streams in the set of data streams and any one or more out of: one or more second data streams in the set of data streams, and a virtual infrastructure model. Based on the relationship indication and the virtual communication model, the first network node triggers a reduction of data to be communicated in the set of data streams.

### TECHNICAL FIELD

Embodiments herein relate to a wireless device, a first network node, a second network node and methods performed therein. Furthermore, a computer program and a carrier are also provided herein. In particular, embodiments herein relate to handling communication of data in a wireless communications network.

### BACKGROUND

In a typical wireless communications network, wireless devices, also known as wireless communication devices, mobile stations, stations (STA) and/or User Equipments (UE), communicate via a Wide Area Network or a Local Area Network such as a Wi-Fi network or a cellular network comprising a Radio Access Network (RAN) part and a Core Network (CN) part. The RAN covers a geographical area which is divided into service areas or cell areas, which may also be referred to as a beam or a beam group, with each service area or cell area being served by a radio network node such as a radio access node e.g., a Wi-Fi access point or a radio base station (RBS), which in some networks may also be denoted, for example, a NodeB, eNodeB (eNB), or gNB as denoted in Fifth Generation (5G) telecommunications. A service area or cell area is a geographical area where radio coverage is provided by the radio network node. The radio network node communicates over an air interface operating on radio frequencies with the wireless device within range of the radio network node.

3GPP is the standardization body for specifies the standards for the cellular system evolution, e.g., including 3G, 4G, 5G and the future evolutions, e.g. 6G. Specifications for the Evolved Packet System (EPS), also called a Fourth Generation (4G) network, have been completed within the 3rd Generation Partnership Project (3GPP). As a continued network evolution, the new releases of 3GPP specifies a 5G network also referred to as 5G New Radio (NR).

Frequency bands for 5G NR are being separated into two different frequency ranges, Frequency Range 1 (FR1) and Frequency Range 2 (FR2). FR1 comprises sub-6 GHz frequency bands. Some of these bands are bands traditionally used by legacy standards but have been extended to cover potential new spectrum offerings from 410 MHz to 7125 MHz FR2 comprises frequency bands from 24.25 GHz to 52.6 GHz. Bands in this millimeter wave range have shorter range but higher available bandwidth than bands in the FR1.

Multi-antenna techniques may significantly increase the data rates and reliability of a wireless communication system. For a wireless connection between a single user, such as UE, and a base station, the performance is in particular improved if both the transmitter and the receiver are equipped with multiple antennas, which results in a Multiple-Input Multiple-Output (MIMO) communication channel. This may be referred to as Single-User (SU)-MIMO. In the scenario where MIMO techniques is used for the wireless connection between multiple users and the base station, MIMO enables the users to communicate with the base station simultaneously using the same time-frequency resources by spatially separating the users, which increases further the cell capacity. This may be referred to as Multi-User (MU)-MIMO. Note that MU-MIMO may benefit when each UE only has one antenna. Such systems and/or related techniques are commonly referred to as MIMO.

For Industry 4.0 operations, it is envisioned that 5G Systems (5GS) will provide necessary performance for the use of Digital Twins (DTs). A DT is a virtual model of a physical entity, i.e. an ongoing simulation of the physical entity and its environment, such as a physical object or an ongoing process in a remote environment. The DT may, in the context of 5G be hosted by a gNB, or any other suitable device. The DT may be supplied with data for the physical entity, wherein the data supplied may be sensor data measured by the physical entity, e.g. by using sensors to measure the environment around the physical entity and/or operations of the physical entity. The gNB may then use the supplied data for the physical entity to create and maintain a virtual model of the physical entity. Using the virtual model, it may thus be possible to simulate how the physical entity will operate under certain scenarios. For example, simulating the physical entity and its environment may enable a dynamic provisioning of Quality of Service (QOS) parameters based on the acquired data of the physical entity.

### SUMMARY

As a part of developing embodiments herein a problem was first identified and will be discussed herein. When operating a simulating a physical entity, e.g. using a DT, a large amount of data needs to be sent over a wireless communications network to be able to accurately simulate the physical entity. Communicating a large amount of data is not always possible, e.g. due to bandwidth constraints, and may thus decrease the performance of the wireless communications network. Hence, to improve the performance of the wireless communications network, there is a need for to reduce the amount of data communicated when simulating physical entities.

An object of embodiments herein is thus to improve the performance of the wireless communications network.

According to an aspect of embodiments herein, the object is achieved by a method performed by a first network node for handling communication of data in a wireless communications network. The first network node manages a virtual communication model. The virtual communication model simulates a communication of a set of data streams between a wireless device and a second network node. The set of data streams is associated with a remotely controlled device. The second network node manages a virtual infrastructure model. The virtual infrastructure model simulates at least part of the remotely controlled device based on the set of data streams. The first network node receives a relationship indication from the second network node. The relationship indication indicates at least one relationship between one or more first data streams in the set of data streams and any one or more out of: one or more second data streams in the set of data streams, and the virtual infrastructure model. Based on the relationship indication and the virtual communication model, the first network node triggers a reduction of data to be communicated in the set of data streams.

According to another aspect of embodiments herein, the object is achieved by a method performed by a second network node for handling communication of data in a wireless communications network. A first network node manages a virtual communication model. The virtual communication model simulates a communication of a set of data streams between a wireless device and the second network node. The set of data streams is associated with a remotely controlled device. The second network node manages a virtual infrastructure model. The virtual infrastructure model simulates at least part of the remotely controlled device based on the set of data streams. The second network node determine at least one relationship between one or more first data streams in the set of data streams and any one or more out of: one or more second data streams in the set of data streams, and the virtual infrastructure model. The second network node transmits a relationship indication to the first network node. The relationship indication indicates the determined at least one relationship.

According to another aspect of embodiments herein, the object is achieved by a method performed by a wireless device for handling communication of data in a wireless communications network. A first network node manages a virtual communication model. The virtual communication model simulates a communication of a set of data streams between the wireless device and a second network node. The set of data streams is associated with a remotely controlled device. The second network node manages a virtual infrastructure model. The virtual infrastructure model simulates at least part of the remotely controlled device based on the set of data streams. The wireless device pre-processes data to be communicated in the set of data streams. The wireless device receives an instruction to adjust the pre-processing of data to be communicated in the set of data streams. The wireless device adjusts the pre-processing of the data to be communicated in the set of data streams based on the received instruction.

According to another aspect of embodiments herein, the object is achieved by a first network node configured to handle communication of data in a wireless communications network. The first network node is further configured to manage a virtual communication model. The virtual communication model simulates a communication of a set of data streams between a wireless device and a second network node. The set of data streams is associated with a remotely controlled device. The second network node manages a virtual infrastructure model. The virtual infrastructure model simulates at least part of the remotely controlled device based on the set of data streams. The first network node is further configured to receive a relationship indication from the second network node. The relationship indication indicates at least one relationship between one or more first data streams in the set of data streams and any one or more out of: one or more second data streams in the set of data streams, and the virtual infrastructure model. The first network node is further configured to, based on the relationship indication and the virtual communication model, trigger a reduction of data to be communicated in the set of data streams.

According to another aspect of embodiments herein, the object is achieved by a second network node configured to handle communication of data in a wireless communications network. A first network node manages a virtual communication model. The virtual communication model simulates a communication of a set of data streams between a wireless device and the second network node. The set of data streams is associated with a remotely controlled device. The second network node is configured to manage a virtual infrastructure model. The virtual infrastructure model simulates at least part of the remotely controlled device based on the set of data streams. The second network node is further configured to determine at least one relationship between one or more first data streams in the set of data streams and any one or more out of: one or more second data streams in the set of data streams, and the virtual infrastructure model. The second network node is further configured to transmit a relationship indication to the first network node. The relationship indication indicates the determined at least one relationship.

According to another aspect of embodiments herein, the object is achieved by a wireless device configured to handle communication of data in a wireless communications network. A first network node manages a virtual communication model. The virtual communication model simulates a communication of a set of data streams between the wireless device and a second network node. The set of data streams is associated with a remotely controlled device. The second network node manages a virtual infrastructure model. The virtual infrastructure model simulates at least part of the remotely controlled device based on the set of data streams. The wireless device is configured to pre-process data to be communicated in the set of data streams. The wireless device is further configured to receive an instruction to adjust a pre-processing of data to be communicated in the set of data streams. The wireless device is further configured to adjust the pre-processing of the data to be communicated in the set of data streams based on the received instruction.

It is furthermore provided herein a computer program comprising instructions, which, when executed on at least one processor, cause the at least one processor to carry out any of the methods above, as performed by the first network node, second network node or the wireless device, respectively. It is additionally provided herein a computer-readable storage medium, having stored thereon a computer program comprising instructions which, when executed on at least one processor, cause the at least one processor to carry out the method according to any of the methods above, as performed by the first network node, second network node or the wireless device, respectively.

Since the second network node determines the at least one relationship and transmits the relationship indication to the first network node, the first network node is capable of determining which data in the set of data streams may be inferred by the set of data streams and/or the virtual infrastructure model. With this knowledge, the first network node is enabled to trigger the reduction of data to be communicated in the set of data streams. Consequently, less data is communicated in the wireless communications network which thus improves the performance.

### BRIEF DESCRIPTION OF THE DRAWINGS

Examples of embodiments herein are described in more detail with reference to attached drawings in which:

FIG. 1 is a schematic block diagram illustrating embodiments of a wireless communications network.

FIG. 2 is a flowchart depicting an embodiment of a method in a first network node.

FIG. 3 is a flowchart depicting an embodiment of a method in a second network node.

FIG. 4 is a flowchart depicting an embodiment of a method in a wireless device.

FIG. 5 is a schematic block diagram illustrating embodiments herein.

FIG. 6 is a combined sequence diagram and flowchart illustrating embodiments herein.

FIG. 7a-b are schematic block diagrams illustrating embodiments of a first network node.

FIG. 8a-b are schematic block diagrams illustrating embodiments of a second network node.

FIG. 9a-b are schematic block diagrams illustrating embodiments of a wireless device.

FIG. 10 schematically illustrates a telecommunications network connected via an intermediate network to a host computer.

FIG. 11 is a generalized block diagram of a host computer communicating via a base station with a user equipment over a partially wireless connection.

FIGS. 12-15 are flowcharts illustrating methods implemented in a communication system including a host computer, a base station and a user equipment.

### DETAILED DESCRIPTION

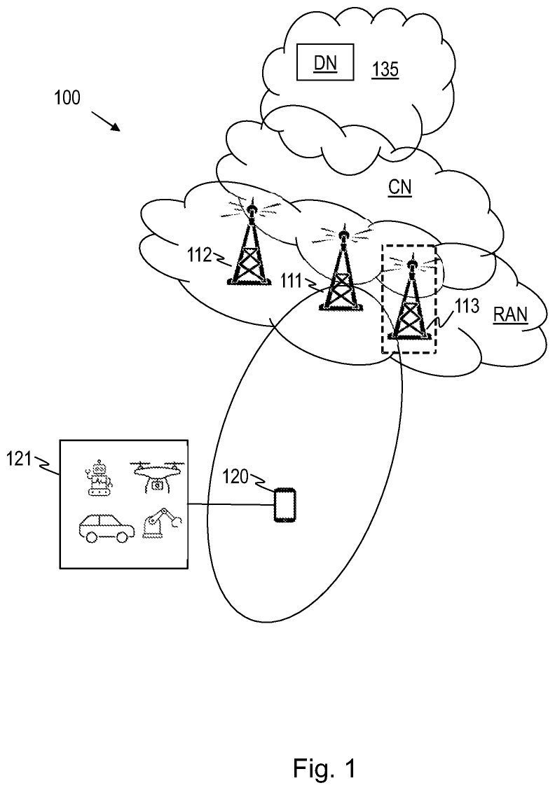

FIG. 1 is a schematic overview depicting a wireless communications network 100 wherein embodiments herein may be implemented. The wireless communications network 100 comprises one or more RANs and one or more CNs. The wireless communications network 100 may use a number of different technologies, such as Wi-Fi, Long Term Evolution (LTE), LTE-Advanced, 5G, NR, Wideband Code Division Multiple Access (WCDMA), Global System for Mobile communications/enhanced Data rate for GSM Evolution (GSM/EDGE), Worldwide Interoperability for Microwave Access (WiMAX), or Ultra Mobile Broadband (UMB), just to mention a few possible implementations. Embodiments herein relate to recent technology trends that are of particular interest in a 5G context, however, embodiments are also applicable in further development of the existing wireless communication systems such as e.g. WCDMA and LTE.

A number of network nodes operate in the wireless communications network 100 such as e.g. a first network node 111, a second network node 112 and a third network node 113. Any one or more out of the first, second, and third network nodes 111, 112, 113 may be co-located or may operate as independent network nodes. Any of the first network node 111, the second network node 112 and the third network node may respectively be any of a NG-RAN node, a base station, a radio access network node such as a Wireless Local Area Network (WLAN) access point or an Access Point Station (AP STA), an access controller, a base station, e.g. a radio base station such as a NodeB, an evolved Node B (eNB, eNode B), a gNB, a base transceiver station, a radio remote unit, an Access Point Base Station, a base station router, a transmission arrangement of a radio base station, a stand-alone access point or any other network unit capable of handling communication, e.g. radio communication, in the wireless communications network 100.

The first network node 111 is configured to manage a virtual communication model which simulates a communication of a set of data streams between a wireless device 120 and the second network node 112. In embodiments herein, the virtual communication model may be a DT of the communication between the wireless device 120 and the second network node 112. In some embodiments, the virtual communication model may be a virtual representation of physical and software instances of at least part of the 5G system in the wireless communications network 100. The virtual communication model may allow to simulate the communication in the set of data streams between the wireless device 120 and the second network node 112. This may involve simulations of future communication requests that may appear, e.g. a novel application traffic model, and/or to investigate a modification in wireless communications network 100. In some embodiments, the virtual communication model allows for investigation of the effect of the changes in the wireless communications network 100 before implementing the changes in the real world. To simulate the communication of the set of data streams, the first network node 111 may be configured to obtain an indication of the communication of the set of data streams. This may be performed in embodiments when the first network node 111 provides radio coverage in a cell to the wireless device 120, and wherein the first network node 111 serves the wireless device 120. In these embodiments the first network node 111 handles the communication of the set of data streams from the wireless device 120 to the second network node 112. Alternatively, the wireless device 120 may also be served in a cell by the third network node 113, wherein the third network node 113 handles the communication of the set of data streams from the wireless device 120 and to the second network node 112. In these embodiments, the third network node 113 transmits the indication of the communication of the set of data streams to the first network node 111. In yet another alternative, the wireless device 120 may also be served in a cell by the second network node 112. In these embodiments, the second network node 112 transmits the indication of the communication of the set of data streams to the first network node 111. The virtual communication model may in these embodiments be a virtual simulated model of how the communications between the wireless device 120 and the second network node 112 takes place, i.e. how data are communicated in the set of data streams.

The second network node 112 is configured to manage a virtual infrastructure model which simulates at least part of a remotely controlled device 121, based on the set of data streams. Simulating the at least part of the remotely controlled device 121 may comprise simulating the environment of which the remotely controlled device 121 operates. The set of data streams may relate to input and output data streams of the remotely controlled device 121, e.g. sensor data measured by the remotely controlled device 121 and/or control data for controlling the remotely controlled device 121. Sensor data as used herein may be physical parameter values measured by one or more sensors associated with the remotely controlled device 121. The virtual infrastructure model may be a DT of the remotely controlled device 121, e.g. including the environment of which the remotely controlled device operates. To simulate the at least part of the remotely controlled device 121, the second network node 112 may be configured to receive the set of data streams from the wireless device 120. The second network node 112 may then simulate the at least part of the remotely controlled device 121 using the data of the set of data streams. The virtual infrastructure model may in these embodiments be a virtual simulated model of how the remotely controlled device 121 operates. The second network node 112 may thus use this virtual infrastructure model, e.g. to determine how some change in the remotely controlled device 121 may affect the input and output data streams related to the remotely controlled device 121.

The third network node 113 may be a network node in-between the wireless device 120 and the second network node 112 and may handle the communication of the set of data streams. The virtual communication model may in some of these embodiments simulate how the third network node 113 handles the communication of the set of data streams.

In the wireless communications network 100, one or more wireless devices operate, such as e.g. the wireless device 120. The wireless device 120 may also be referred to as a UE, an internet of things (IoT) device, a mobile station, a non-access point (non-AP) STA, a STA, and/or a wireless terminals. The wireless device 120 communicate via one or more Access Networks (AN), e.g. RAN, to one or more Core Networks (CN). It should be understood by the skilled in the art that “wireless device” or UE, is a non-limiting term which means any terminal, wireless communication terminal, user equipment, Machine Type Communication (MTC) device, Device to Device (D2D) terminal, or node e.g. smart phone, laptop, mobile phone, sensor, relay, mobile tablets or even a small base station communicating within a cell. The wireless device 120 may be in communication with the remotely controlled device 121 or it may comprise and/or be co-located with the remotely controlled device 121. The input and output data streams related to the remotely controlled device 121 may be obtained by the wireless device 120, e.g. by receiving them from the remotely controlled device 121. The wireless device 120 is further configured to pre-process the data of the input and output data streams. Pre-processing the data may relate to encoding the data of the input and output data streams to be data packets for communication in the set of data streams.

The remotely controlled device 121 may obtain the input and output data streams related to the remotely controlled device 121. This may be performed by measuring sensor data and/or by receiving control data, e.g. for controlling the remotely controlled device 121. The remotely controlled device 121 may be realized by various devices such as e.g. a remotely controlled vehicle, industrial robot, etc. The remotely controlled device 121 may be a part of the wireless device 120 or may be an independent unit which transmits the input and output data streams related to the remotely controlled device 121 to the wireless device 120.

A data stream in the set of data streams as used herein may be represented by one or more data packets relating to the same type of data. The one or more data packets may be communicated regularly between the wireless device 120 and the second network node 112 and/or triggered by an event. The one or more data packets may comprise sensor data from the remotely controlled device 121 and/or control data for controlling the remotely controlled device 121. The sensor data may be represented by values measured by one or more sensors, e.g. comprised in the remotely controlled device 121.

Methods herein may be performed by the first network node 111, the second network node 112 and/or the wireless device 120. As an alternative, a Distributed Node (DN) and functionality, e.g. comprised in a cloud 135 as shown in FIG. 1, may be used for performing or partly performing the methods herein.

Embodiments herein may relate to correlation of different components of the virtual infrastructure model and the virtual communication model to minimize user plane traffic in the wireless communications network 100. This may be achieved by using the virtual infrastructure model and the virtual communication model to deduce which part of data communicated in the set of data streams is needed to for the virtual infrastructure model to simulate the remotely controlled device 121. When some data in the set of data streams can be deduced e.g. by other data streams in the set of data streams, the virtual communication model may be used to determine whether or not it is possible to achieve a reduction in data communication by, e.g. dropping some packets in the set of data streams and/or by adjusting the pre-processing of the data communicated in the set of data streams. In this way, the embodiments herein enable to reduce the data communicated in the wireless communications network 100 while still properly maintaining the virtual infrastructure model in the second network node 112.

A number of embodiments will now be described, some of which may be seen as alternatives, while some may be used in combination.

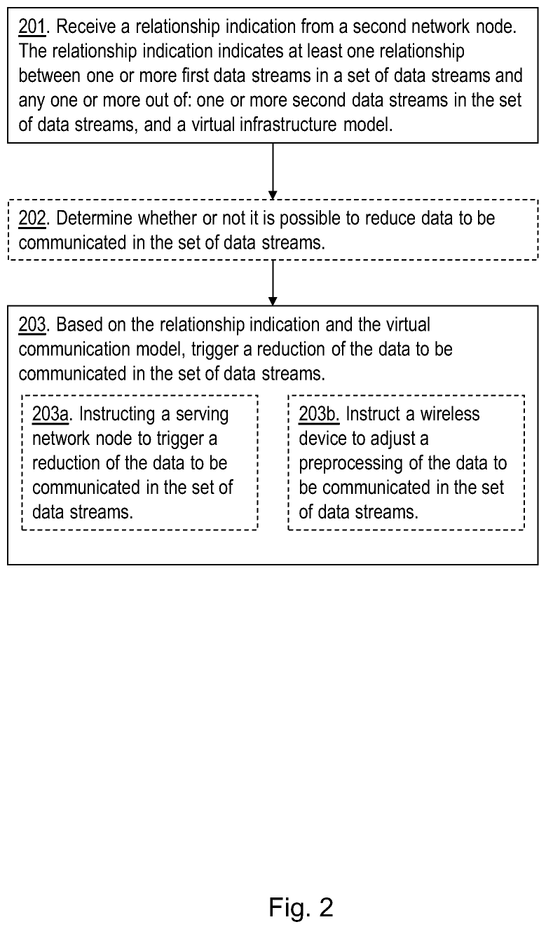

FIG. 2 shows example embodiments of a method performed by the first network node 111 for handling communication of data in the wireless communications network 100. The first network node 111 manages the virtual communication model. The virtual communication model simulates a communication of a set of data streams between the wireless device 120 and the second network node 112. The set of data streams is associated with the remotely controlled device 121. The second network node 112 manages the virtual infrastructure model. The virtual infrastructure model simulates at least part of the remotely controlled device 121 based on the set of data streams. The method comprises the following actions, which actions may be taken in any suitable order. Optional actions are referred to as dashed boxes in FIG. 2.

Action 201. The first network node 111 receives from the second network node 112, a relationship indication, wherein the relationship indication indicates at least one relationship between one or more first data streams in the set of data streams and any one or more out of: one or more second data streams in the set of data streams, and the virtual infrastructure model. For example, when the relationship indication indicates a relationship between one or more first data streams in the set of data streams and one or more second data streams in the set of data streams, the relationship may indicate that the one or more first data streams may be deduced and/or predicted by the one or more second data streams in the set of data streams. This may be since the one or more second data streams may relate to a sufficiently similar data as the one or more first data streams, e.g. they may both relate to a rotational speed of a respective wheel in embodiments where the remotely controlled vehicle 121 is a remotely controlled car. The respective wheel may thus in some embodiments be approximated to have the same rotational speed. As another example, knowledge of the one or more second data streams may imply at least parts of data in the one or more first data streams. Hence, the at least one relationship may indicate how the one or more first data streams relate to the second one or more data streams. Additionally or alternatively, when the relationship indication indicates at least one relationship between the one or more first data streams and the virtual infrastructure model, the at least one relationship may relate to indicating how the data in the one or more first data streams relate to the virtual infrastructure model, e.g. the impact of the one or more first data streams on the virtual infrastructure model. This may be indicated by a tolerable error margin and/or a correlation factor for any one or more out of the data streams in the set of data streams. In some scenarios, the at least one relationship may indicate that the virtual infrastructure model may be able to be simulated by the second network node 112 without the one or more first data streams. In some embodiments, the at least one relationship may indicate that the data communicated in the one or more first data streams may be possible to approximate, e.g. as a constant or a function, and may thus only need to be transmitted once. In some embodiments, the at least one relationship may indicate that the data communicated in the one or more first data streams may not change often and/or may not vary significantly, hence, the data in the one or more first data streams may only be needed to be communicated rarely. In this way, the at least one relationship may indicate the significance, e.g. when and how the data is needed, of at least some data in the one or more first data streams with respect to the virtual infrastructure model.

Action 202. In some embodiments, the first network node 111, based on the at least one relationship and the virtual communication model, determines whether or not it is possible to reduce the data to be communicated in the set of data streams. In some embodiments, determining whether or not it is possible to reduce the data to be communicated in the set of data streams is based on simulating communication of the set of data streams using the virtual communication model. In some embodiments, the first network node 111 determines that it is possible to reduce the data in the set of data streams, e.g. by dropping one or more packets in any one or more streams in the set of data streams, and/or by adjusting the pre-processing of data to be communicated in the set of data streams. In some embodiments, determining that it is possible to reduce the data to be communicated in the set of streams may comprise determining that the amount of data to be reduced, e.g. a data size transmitted over a period of time in the set of data streams, will be reduced by more than a threshold when triggering the reduction of data to be communicated in the set of data streams. In some embodiments, determining whether or not it is possible to reduce the data to be communicated in the set of data streams may comprise determining whether or not the virtual infrastructure model will properly function when triggering the reduction of data. In one example scenario, the first network node 111 may, by the at least one relationship, be informed that the first data streams in the set of data streams may be deduced by the one or more second data streams. Hence, in this scenario the one or more first data streams may be excluded from the set of data streams. As another example scenario, the first network node 111 may again be informed that the first data streams in the set of data streams may be deduced by the one or more second data streams. The at least one relationship may further indicate that the deduction can only be made with a first error margin and/or first correlation factor. Furthermore, the at least one relationship may also specify that the error margin and/or the correlation factor for the data in the one or more first data stream need to be lower than the first error margin and/or first correlation factor in order for the virtual infrastructure model to properly function. Hence, in this scenario it may not be possible to reduce the data as the error margin would be too severe for the virtual infrastructure model to function properly.

Action 203. The first network node 111, based on the relationship indication and the virtual communication model, triggers a reduction of data to be communicated in the set of data streams. In this way, the first network node 111 may ensure that the data is reduced in the set of data streams. This may involve indicating how the set of data streams should be reduced without losing functionality of the virtual infrastructure model. In some embodiments, the first network node 111 triggers the reduction of data when it is determined to be possible to reduce the data to be communicated in the set of data streams.

Action 203a. In some embodiments, the first network node 111 triggers the reduction of the data to be communicated in the set of data streams by instructing a serving network node 111, 112, 113 to trigger the reduction of the data to be communicated in the set of data streams. The first network node 111 may need to instruct the network node handling the data between the wireless device 120 and the second network node 112 to reduce the data to be communicated in the set of data streams, e.g. to drop one or more packets in the set of data streams and/or to reorganize the set of data streams into a new set of data streams. Hence, the serving network node which handles the communication of the set of data streams may need to be instructed to reduce the data to be communicated in the set of data streams. The serving network node may be any one out of the first network node 111, the second network node 112 and the third network node 113. In these embodiments, the wireless device 120 is served in a cell by the serving network node. In some embodiments, the first network node 111 instructs the serving network node to trigger the reduction of the data to be communicated in the set of data streams by instructing the serving network node to drop one or more data packets in the set of data streams. In this way, a reduction of data in the set of data streams is achieved. Additionally or alternatively, the first network node 111 instructs the serving network node to trigger the reduction of the data to be communicated in the set of data streams by instructing the serving network node to instruct the wireless device 120 to adjust a pre-processing of the data to be communicated in the set of data streams. In other words, the serving network node may relay an instruction to reduce the data in the set of data streams to the wireless device 120.

Action 203b. In some embodiments, the first network node 111 triggers the reduction of the data to be communicated in the set of data streams by instructing the wireless device 120 to adjust the pre-processing of the data to be communicated in the set of data streams. In this way, the wireless device 120 may thus adjust the pre-processing of the data to be communicated in the set of data streams, e.g. by excluding the one or more first data streams from being communicated in the set of data streams.

In above actions 203a and 203b, the instructions may comprise an indication of which data to exclude from data to be communicated in the set of data streams and/or how often certain data in the set of data streams are needed, e.g. for the virtual infrastructure model to function properly.

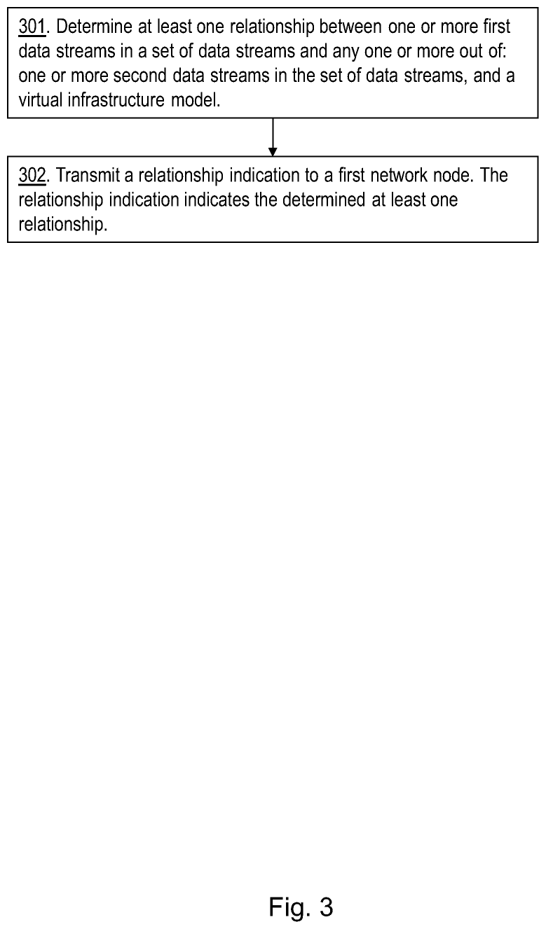

FIG. 3 shows example embodiments of a method performed by the second network node 112 for handling communication of data in the wireless communications network 100. The first network node 111 manages the virtual communication model. The virtual communication model simulates a communication of a set of data streams between the wireless device 120 and the second network node 112. The set of data streams is associated with the remotely controlled device 121. The second network node 112 manages the virtual infrastructure model. The virtual infrastructure model simulates at least part of the remotely controlled device 121 based on the set of data streams. The method comprises the following actions, which actions may be taken in any suitable order. Optional actions are referred to as dashed boxes in FIG. 3.

Action 301. The second network node 112 determines at least one relationship between one or more first data streams in the set of data streams and any one or more out of: one or more second data streams in the set of data streams, and the virtual infrastructure model. In other words, the at least one relationship e.g. may be determined to indicate how the one or more first data streams are related to the second one or more data streams and/or to the virtual infrastructure model, e.g. as describe in above Action 201. In some embodiments, the second network node 112 determines the at least one relationship between the one or more first data streams in the set of data streams and the one or more second data streams in the set of data streams comprises determining that at least part of the data communicated in the one or more first data streams is deducible based on the one or more second data streams. For example, the at least one relationship may be determined to indicate that two different data streams may describe the same or similar data, e.g. two temperature sensors may feed two different data streams for redundancy. As another example, the at least one relationship may be determined to indicate that a location sensor data stream may be able to determine a velocity sensor data stream, e.g. as it is possible to deduce velocity from a plurality of location data. In some embodiments, the second network node 112 determines the at least one relationship between the one or more first data streams in the set of data streams and the virtual infrastructure model comprises determining a functionality of the virtual infrastructure model based on at least part of the data communicated in the one or more first data streams. In these embodiments, the at least one relationship may be determined to indicate that the one or more first data streams may e.g. be estimated to be a constant or a function, e.g. as the virtual infrastructure model do not rely much on the one or more set of data streams. Additionally or alternatively, the at least one relationship may be determined to indicate that the one or more first data streams may only relate to a first error margin for the virtual infrastructure model to work properly. Additionally or alternatively, the at least one relationship may be determined to indicate that the one or more first data streams may be essential to the virtual infrastructure model and is always needed for the virtual infrastructure model to properly function. In some embodiments, determining the at least one relationship may be based on simulating the remotely controlled device 121 using the virtual infrastructure model.

Action 302. The second network node 112 transmits the relationship indication to the first network node 111. The relationship indication indicates the determined at least one relationship. In this way, the first network node 111 is enabled to reduce the data communicated in the set of data streams based on the transmitted relationship indication.

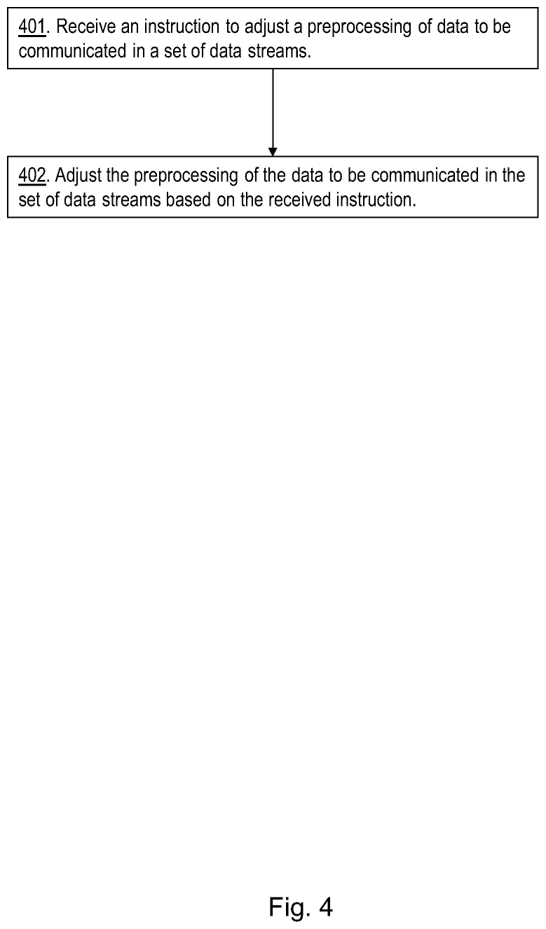

FIG. 4 shows example embodiments of a method performed by the wireless device 120 for handling communication of data in the wireless communications network 100. The first network node 111 manages the virtual communication model. The virtual communication model simulates the communication the set of data streams between the wireless device 120 and the second network node 112. The set of data streams is associated with the remotely controlled device 121. The second network node 112 manages the virtual infrastructure model. The virtual infrastructure model simulates at least part of the remotely controlled device 121 based on the set of data streams. The wireless device 120 pre-processes data to be communicated in the set of data streams. In some of these embodiments, pre-processing the data to be communicated in the set of data streams may comprise any one or more out of the following preparatory actions. The wireless device 120 may obtain the input and output data streams of the remotely controlled device 121. In embodiments when the remotely controlled device 121 is part of, or co-located with the wireless device 120, the input and output data streams of the remotely controlled device 121 may be measured or otherwise obtained locally by sensors and/or by internal calculations. The wireless device 120 may alternatively receive the input and output data streams of the remotely controlled device 121 from the remotely controlled device 121. The wireless device 120 may process the input and output data streams of the remotely controlled device 121 to be in a proper communication format to communicate the data to be communicated in the set of data streams. The wireless device 120 may organize the data to be communicated into one or more data streams, e.g. by determining a number of data streams in the set of data streams and/or what type of data is to be communicated in each data stream in the set of data streams. The wireless device 120 may further select which part of the obtained data in the input and output data streams of the remotely controlled device 121 to be communicated in the set of data streams. The set of data streams may thus be a subset of the input and output data streams of the remotely controlled device 121. The set of data streams may also comprise all data in the set input and output data streams of the remotely controlled device 121.

The method comprises the following actions, which actions may be taken in any suitable order. Optional actions are referred to as dashed boxes in FIG. 4.

Action 401. The wireless device 120 receives an instruction to adjust a pre-processing of data to be communicated in the set of data streams. The instruction may be received by the first network node 111 and/or the serving network node, e.g. as transmitted in above actions 203a and/or 203b. The instruction may comprise an indication of which data to exclude from data to be communicated in the set of data streams.

Action 402. The wireless device 120 adjusts the pre-processing of the data to be communicated in the set of data streams based on the received instruction. In some embodiments, the wireless device 120 adjusts the pre-processing of the data to be communicated in the set of data streams by reducing the data to be communicated in the set of data streams by any one or more out of: refraining from communicating one or more data streams in the set of data streams, refraining from communicating at least one data packet in one or more data streams in the set of data streams, and/or adjusting a frequency for communicating data in at least one or more data streams in the set of data streams. For example, the instruction may indicate that one data stream may be excluded from the data to be communicated in the set of data streams, in which case the pre-processing in the wireless device 120 may exclude the data from the set of data streams. In some embodiments, the instruction may however only indicate that part of data in one or more data streams in the set of data streams is to be excluded. In these embodiments the wireless device 120 may exclude some of the packets related to the one or more data streams. In some embodiments, the instruction may indicate that data is not needed so often, e.g. only one update every second will suffice for the virtual infrastructure model to function properly. In this case the wireless device 120 may adjust the frequency for how often to send data packets, e.g. of a certain data type, in the set of data streams.

The above embodiments will now be further explained and exemplified below. The embodiments below may be combined with any suitable embodiment above.

The embodiments herein may relate to correlating components of the virtual infrastructure model and the virtual communication model, both which may be DTs. The result of the correlation, e.g. the at least one relationship, may as shown in embodiments herein, reduce the data communicated in the wireless communications network 100, e.g. relating to the virtual infrastructure model. This may be since, the interaction with a 5G network digital twin, e.g. the virtual communication model, and infrastructure digital twin, e.g. the virtual infrastructure model, may help to reveal correlated components.

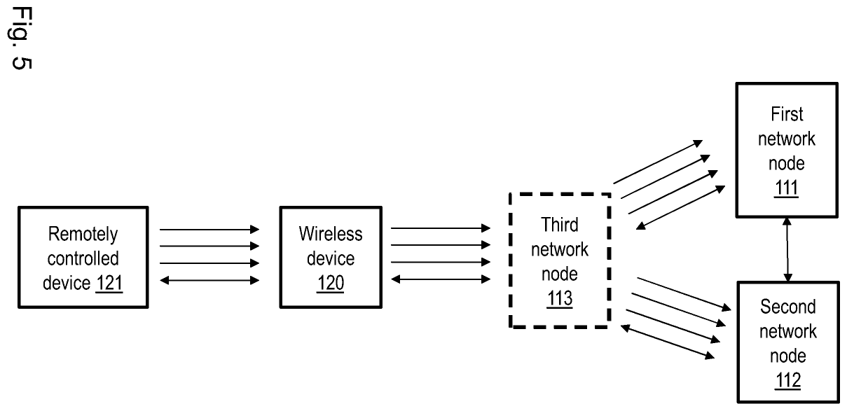

The embodiments herein may be exemplified by the example scenario in FIG. 5. The remotely controlled device 121 may communicate the input and output data streams with the wireless device 120. The wireless device 120 may pre-process the input and output data streams to produce the set of data streams. The wireless device 120 may communicate the set of data streams with the second network node 112, this communication may be handled by the third network node 113, e.g. which also transmits the set of data streams, or an indication of the set of data streams to the first network node 111. The second network node 112 determines the at least one relationship of the set of data streams and transmits the relationship indication to the first network node 111. The first network node 111 may then, based on the relationship indication trigger the reduction of the data communicated in the set of data streams.

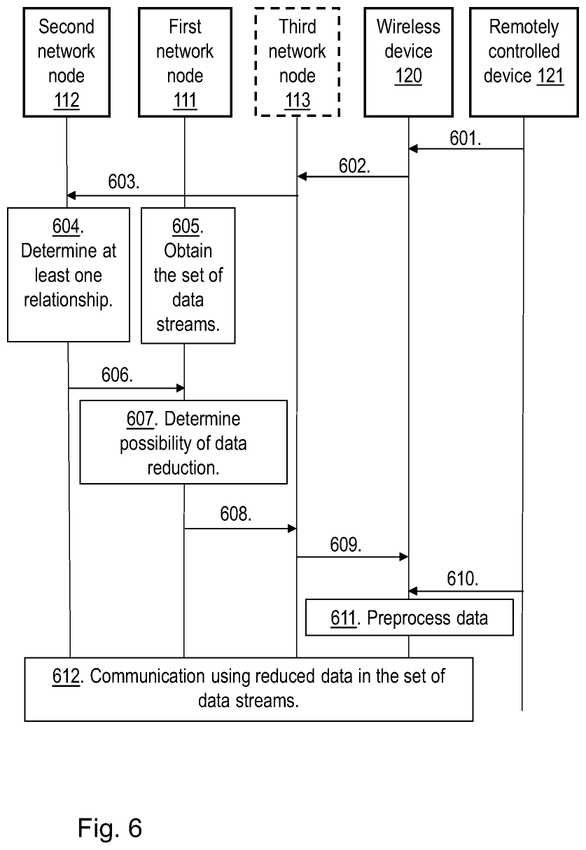

Example communication scenario. An example scenario is illustrated in FIG. 6 which summarize the communication between the first network node 111, second network node 112, optionally the third network node 113, the wireless device 120, and the remotely controlled device 121, and their respective actions performed. Below actions are an example, and hence the actions and communications below may be performed when suitable, in any suitable order. Further, the example scenario of FIG. 6. may assume that the virtual infrastructure model is known by the first network node 111 and/or the virtual communication model.

Action 601. The wireless device 120 obtains the input and output data streams, e.g. received by the remotely controlled device 121. The wireless device 120 may pre-process the input and output data streams to be able to communicate the set of data streams, e.g. as described with reference to FIG. 4.

Action 602. In this scenario, the wireless device 120 transmits the set of data streams to the second network node 112 via the third network node 113, e.g. acting as the serving network node. The wireless device 120 may be served by the first network node 111 and may transmit the set of data streams to the second network node 112 via the first network node 111. The wireless device 120 may further be served by the second network node 112 and may transmit the set of data streams directly to the second network node 112.

Action 603. In this scenario, the third network node 113 handles the communication of the set of data streams and transmits, e.g. relays, the set of data streams to the second network node 112. The third network node 113 may in this scenario also transmit the set of data streams, or an indication of the set of data streams to the first network node 111.

Action 604. The second network node 112 determines the at least one relationship, e.g. as in action 301. The second network node 112 may also simulate the remotely controlled device 121, e.g. using the set of data streams.

Action 605. The first network node 111 obtains the set of data streams or an indication of the set of data streams. In this scenario, the first network node 111 received the set of data streams from the third network node 113, however, the set of data streams or the indication of the set of data streams may also be received from the wireless device 120, or the second network node 112, e.g. depending on which network node 111, 112, 113 is serving the wireless device 120. The first network node 111 may then simulate the communication of the set of data streams, e.g. using the virtual communication model, based on the indication of the set of data streams or based on the set of data streams.

Action 606. The second network node 112 transmits to the first network node 111, the relationship indication. This may be performed as described in action 302.

Action 607. The first network node 111 determines the possibility to reduce data in the set of data streams. This may be performed as described in action 202.

Action 608. In this scenario, the first network node 111 transmits an instruction to trigger the reduction of data to the third network node 113. The instruction to trigger the reduction of data may alternatively be transmitted to the serving network node 111, 112, 113. This may cause the serving network node, i.e. the first network node 111, the second network node 112, or the third network node 113 to enforce the data reduction triggered by the first network node 111. This may e.g. be achieved by dropping packets in the set of data streams. The first network node 111 may alternatively or additionally instruct the wireless device 120 to trigger the reduction of data, e.g. by adjusting the pre-processing as mentioned above. This may relate to action 203a.

Action 609. The third network node 113 enforces the data reduction by instructing the wireless device 120 to adjust the pre-processing of the data in the set of data streams. This may relate to action 203b.

Action 610. The wireless device 120 may receive new data in the input and output data streams.

Action 611. The wireless device 120 pre-processes the new data in the input and output data streams, e.g. as instructed in action 608 and/or action 609.

Action 612. The communication of the set of data streams is now performed using a reduced data.

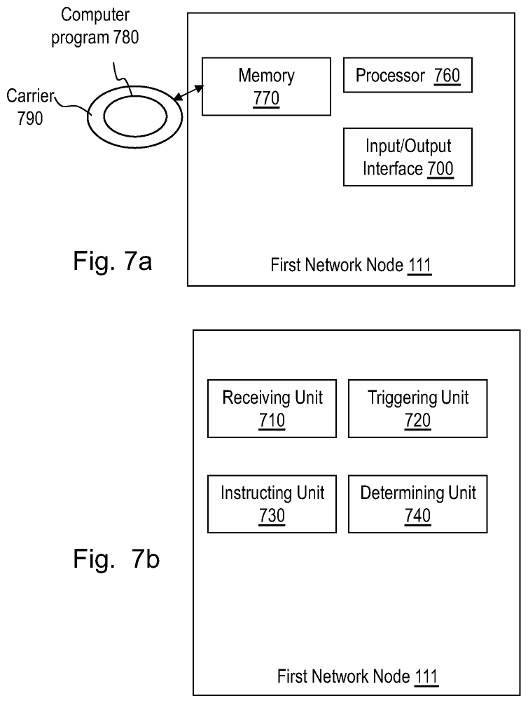

First network node 111 implementation. To perform the method actions above, the first network node 111 is configured to handle communication of data in the wireless communications network 100. The first network node 111 is further configured to manage the virtual communication model. The virtual communication model simulates the communication of the set of data streams between the wireless device 120 and the second network node 112. The set of data streams is associated with the remotely controlled device 121. The second network node 112 manages the virtual infrastructure model. The virtual infrastructure model simulates at least part of the remotely controlled device 121 based on the set of data streams. The first network node 111 may comprise an arrangement depicted in FIGS. 7a and 7b. The first network node 111 may comprise an input and output interface 700 configured to communicate with e.g. the second network node 112, the third network node 112, and/or the wireless device 120. The input and output interface 700 may comprise a wireless receiver (not shown) and a wireless transmitter (not shown).

The first network node 111 may further be configured to, e.g. by means of a receiving unit 710 in the first network node 111, receive from the second network node 112, the relationship indication, wherein the relationship indication indicates at least one relationship between one or more first data streams in the set of data streams and any one or more out of: one or more second data streams in the set of data streams, and the virtual infrastructure model.

The first network node 111 may further be configured to, e.g. by means of a triggering unit 720 in the first network node 111, based on the relationship indication and the virtual communication model, trigger the reduction of data to be communicated in the set of data streams.

The first network node 111 may further be configured to, e.g. by means of an instructing unit 730 in the first network node 111, trigger the reduction of the data to be communicated in the set of data streams by any one or more out of:
instructing a serving network node to trigger the reduction of the data to be communicated in the set of data streams, wherein the wireless device is served in a cell by the serving network node, and
instructing the wireless device 120 to adjust a pre-processing of the data to be communicated in the set of data streams.

The first network node 111 may further be configured to, e.g. by means of the instructing unit 730 in the first network node 111, instruct the serving network node 111, 112, 113 to trigger the reduction of the data to be communicated in the set of data streams by any one or more out of:
instructing the serving network node to drop one or more data packets in the set of data streams, and
instructing the serving network node to instruct the wireless device 120 to adjust the pre-processing of the data to be communicated in the set of data streams.

The first network node 111 may further be configured to, e.g. by means of a determining unit 740 in the first network node 111, based on the at least one relationship and the virtual communication model, determine whether or not it is possible to reduce the data to be communicated in the set of data streams.

The first network node 111 may further be configured to, e.g. by means of the triggering unit 720 in the first network node 111, trigger the reduction of data when it is determined to be possible to reduce the data to be communicated in the set of data streams.

The embodiments herein may be implemented through a respective processor or one or more processors, such as the processor 760 of a processing circuitry in the first network node 111 depicted in FIG. 7a, together with respective computer program code for performing the functions and actions of the embodiments herein. The program code mentioned above may also be provided as a computer program product, for instance in the form of a data carrier carrying computer program code for performing the embodiments herein when being loaded into the first network node 111. One such carrier may be in the form of a CD ROM disc. It is however feasible with other data carriers such as a memory stick. The computer program code may furthermore be provided as pure program code on a server and downloaded to the first network node 111.

The first network node 111 may further comprise a memory 770 comprising one or more memory units. The memory 770 comprises instructions executable by the processor in first network node 111. The memory 770 is arranged to be used to store e.g. information, indications, relationships, configurations, data, data streams, and applications to perform the methods herein when being executed in the first network node 111.

In some embodiments, a computer program 780 comprises instructions, which when executed by the respective at least one processor 760, cause the at least one processor of the first network node 111 to perform the actions above.

In some embodiments, a respective carrier 790 comprises the respective computer program 780, wherein the carrier 790 is one of an electronic signal, an optical signal, an electromagnetic signal, a magnetic signal, an electric signal, a radio signal, a microwave signal, or a computer-readable storage medium.

Those skilled in the art will appreciate that the units in the first network node 111 described above may refer to a combination of analog and digital circuits, and/or one or more processors configured with software and/or firmware, e.g. stored in the first network node 111, that when executed by the respective one or more processors such as the processors described above. One or more of these processors, as well as the other digital hardware, may be included in a single Application-Specific Integrated Circuitry (ASIC), or several processors and various digital hardware may be distributed among several separate components, whether individually packaged or assembled into a system-on-a-chip (SoC).

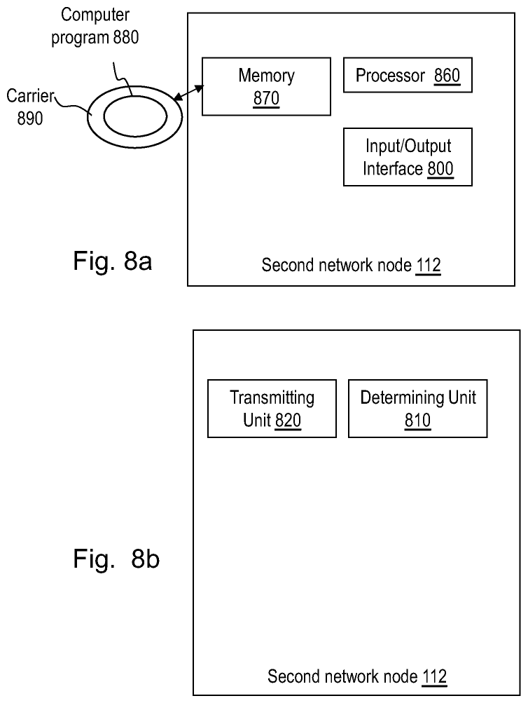

Second network node 112 implementation. To perform the method actions above, the second network node 112 is configured to handle communication of data in a wireless communications network 100. The first network node 111 manages the virtual communication model. The virtual communication model simulates the communication of the set of data streams between the wireless device 120 and the second network node 112. The set of data streams is associated with a remotely controlled device 121. The second network node 112 is configured to manage a virtual infrastructure model. The virtual infrastructure model simulates at least part of the remotely controlled device 121 based on the set of data streams. The second network node 112 may comprise an arrangement depicted in FIGS. 8a and 8b. The second network node 112 may comprise an input and output interface 800 configured to communicate with e.g. the first network node 111, the third network node 112, and/or the wireless device 120. The input and output interface 800 may comprise a wireless receiver (not shown) and a wireless transmitter (not shown).

The second network node 112 may further be configured to, e.g. by means of a determining unit 810 in the second network node 112, determine at least one relationship between one or more first data streams in the set of data streams and any one or more out of:
one or more second data streams in the set of data streams, and
the virtual infrastructure model.

The second network node 112 may further be configured to, e.g. by means of the determining unit 810 in the second network node 112, determine the at least one relationship between the one or more first data streams in the set of data streams and the one or more second data streams in the set of data streams comprises determining that at least part of the data communicated in the one or more first data streams is deducible based on the one or more second data streams.

The second network node 112 may further be configured to, e.g. by means of the determining unit 810 in the second network node 112, determine the at least one relationship between the one or more first data streams in the set of data streams and the virtual infrastructure model by determining a functionality of the virtual infrastructure model based on at least part of the data communicated in the one or more first data streams

The second network node 112 may further be configured to, e.g. by means of a transmitting unit 820 in the second network node 112, transmit a relationship indication to the first network node 111, wherein the relationship indication indicates the determined at least one relationship.

The embodiments herein may be implemented through a respective processor or one or more processors, such as the processor 860 of a processing circuitry in the second network node 112 depicted in FIG. 8a, together with respective computer program code for performing the functions and actions of the embodiments herein. The program code mentioned above may also be provided as a computer program product, for instance in the form of a data carrier carrying computer program code for performing the embodiments herein when being loaded into the second network node 112. One such carrier may be in the form of a CD ROM disc. It is however feasible with other data carriers such as a memory stick. The computer program code may furthermore be provided as pure program code on a server and downloaded to the second network node 112.

The second network node 112 may further comprise a memory 870 comprising one or more memory units. The memory 870 comprises instructions executable by the processor in second network node 112. The memory 870 is arranged to be used to store e.g. information, indications, relationships, configurations, sensor data, data, data streams, and applications to perform the methods herein when being executed in the second network node 112.

In some embodiments, a computer program 880 comprises instructions, which when executed by the respective at least one processor 860, cause the at least one processor of the second network node 112 to perform the actions above.

In some embodiments, a respective carrier 890 comprises the respective computer program 880, wherein the carrier 890 is one of an electronic signal, an optical signal, an electromagnetic signal, a magnetic signal, an electric signal, a radio signal, a microwave signal, or a computer-readable storage medium.

Those skilled in the art will appreciate that the units in the second network node 112 described above may refer to a combination of analog and digital circuits, and/or one or more processors configured with software and/or firmware, e.g. stored in the second network node 112, that when executed by the respective one or more processors such as the processors described above. One or more of these processors, as well as the other digital hardware, may be included in a single Application-Specific Integrated Circuitry (ASIC), or several processors and various digital hardware may be distributed among several separate components, whether individually packaged or assembled into a system-on-a-chip (SoC).

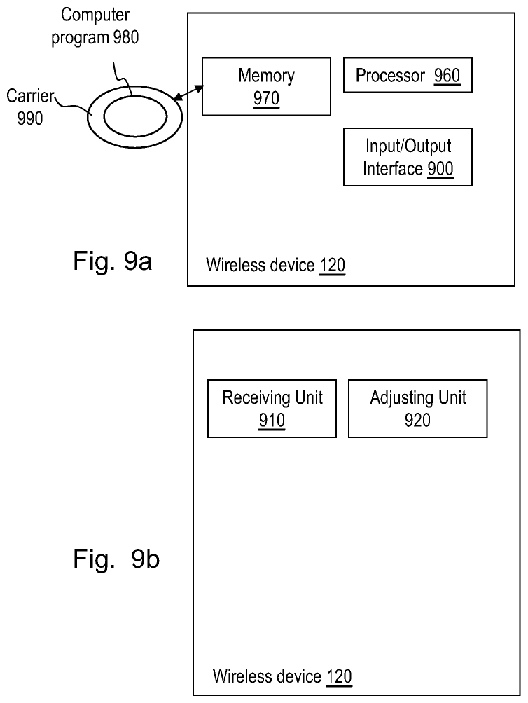

Wireless device 120 implementation. To perform the method actions above, the wireless device 120 is configured to handle communication of data in the wireless communications network 100. The first network node 111 manages the virtual communication model. The virtual communication model simulates the communication of the set of data streams between the wireless device 120 and the second network node 112. The set of data streams is associated with a remotely controlled device 121. The second network node 112 manages the virtual infrastructure model. The virtual infrastructure model simulates at least part of the remotely controlled device 121 based on the set of data streams. The wireless device 120 is configured to pre-process data communicated in the set of data streams. The wireless device 120 may comprise an arrangement depicted in FIGS. 9a and 9b. The wireless device 120 may comprise an input and output interface 900 configured to communicate with e.g. the first network node 111, the second network node 112, the third network node 113 and/or the remotely controlled device 121. The input and output interface 900 may comprise a wireless receiver (not shown) and a wireless transmitter (not shown).

The wireless device 120 may further be configured to, e.g. by means of a receiving unit 910 in the wireless device 120, receive an instruction to adjust a pre-processing of data to be communicated in the set of data streams.

The wireless device 120 may further be configured to, e.g. by means of an adjusting unit 920 in the wireless device 120, adjust the pre-processing of the data to be communicated in the set of data streams based on the received instruction.

The wireless device 120 may further be configured to, e.g. by means of the adjusting unit 920 in the wireless device 120, adjust the pre-processing of the data to be communicated in the set of data streams by reducing the data to be communicated in the set of data streams by any one or more out of:
refraining from communicating one or more data streams in the set of data streams,
refraining from communicating at least one data packet in one or more data streams in the set of data streams, and
adjusting a frequency for communicating data in at least one or more data streams in the set of data streams.

The embodiments herein may be implemented through a respective processor or one or more processors, such as the processor 960 of a processing circuitry in the wireless device 120 depicted in FIG. 9a, together with respective computer program code for performing the functions and actions of the embodiments herein. The program code mentioned above may also be provided as a computer program product, for instance in the form of a data carrier carrying computer program code for performing the embodiments herein when being loaded into the wireless device 120. One such carrier may be in the form of a CD ROM disc. It is however feasible with other data carriers such as a memory stick. The computer program code may furthermore be provided as pure program code on a server and downloaded to the wireless device 120.

The wireless device 120 may further comprise a memory 970 comprising one or more memory units. The memory 970 comprises instructions executable by the processor in wireless device 120. The memory 970 is arranged to be used to store e.g. information, indications, relationships, configurations, sensor data, data, data streams, and applications to perform the methods herein when being executed in the wireless device 120.

In some embodiments, a computer program 980 comprises instructions, which when executed by the respective at least one processor 960, cause the at least one processor of the wireless device 120 to perform the actions above.

In some embodiments, a respective carrier 990 comprises the respective computer program 980, wherein the carrier 990 is one of an electronic signal, an optical signal, an electromagnetic signal, a magnetic signal, an electric signal, a radio signal, a microwave signal, or a computer-readable storage medium.

Those skilled in the art will appreciate that the units in the wireless device 120 described above may refer to a combination of analog and digital circuits, and/or one or more processors configured with software and/or firmware, e.g. stored in the wireless device 120, that when executed by the respective one or more processors such as the processors described above. One or more of these processors, as well as the other digital hardware, may be included in a single Application-Specific Integrated Circuitry (ASIC), or several processors and various digital hardware may be distributed among several separate components, whether individually packaged or assembled into a system-on-a-chip (SoC).

With reference to FIG. 10, in accordance with an embodiment, a communication system includes a telecommunications network 3210 such as the wireless communications network 100, e.g. an IoT network, or a WLAN, such as a 3GPP-type cellular network, which comprises an access network 3211, such as a radio access network, and a core network 3214. The access network 3211 comprises a plurality of base stations 3212a, 3212b, 3212c, such as the first network node 111, and/or the second network node 112, access nodes, AP STAs NBs, eNBs, gNBs or other types of wireless access points, each defining a corresponding coverage area 3213a, 3213b, 3213c. Each base station 3212a, 3212b, 3212c is connectable to the core network 3214 over a wired or wireless connection 3215. A first user equipment (UE) e.g. the wireless device 120 such as a Non-AP STA 3291 located in coverage area 3213c is configured to wirelessly connect to, or be paged by, the corresponding base station 3212c. A second UE 3292 e.g. the wireless device 120, such as a Non-AP STA in coverage area 3213a is wirelessly connectable to the corresponding base station 3212a. While a plurality of UEs 3291, 3292 are illustrated in this example, the disclosed embodiments are equally applicable to a situation where a sole UE is in the coverage area or where a sole UE is connecting to the corresponding base station 3212.

The telecommunications network 3210 is itself connected to a host computer 3230, which may be embodied in the hardware and/or software of a standalone server, a cloud-implemented server, a distributed server or as processing resources in a server farm. The host computer 3230 may be under the ownership or control of a service provider, or may be operated by the service provider or on behalf of the service provider. The connections 3221, 3222 between the telecommunications network 3210 and the host computer 3230 may extend directly from the core network 3214 to the host computer 3230 or may go via an optional intermediate network 3220. The intermediate network 3220 may be one of, or a combination of more than one of, a public, private or hosted network; the intermediate network 3220, if any, may be a backbone network or the Internet; in particular, the intermediate network 3220 may comprise two or more sub-networks (not shown).

The communication system of FIG. 10 as a whole enables connectivity between one of the connected UEs 3291, 3292 and the host computer 3230. The connectivity may be described as an over-the-top (OTT) connection 3250. The host computer 3230 and the connected UEs 3291, 3292 are configured to communicate data and/or signaling via the OTT connection 3250, using the access network 3211, the core network 3214, any intermediate network 3220 and possible further infrastructure (not shown) as intermediaries. The OTT connection 3250 may be transparent in the sense that the participating communication devices through which the OTT connection 3250 passes are unaware of routing of uplink and downlink communications. For example, a base station 3212 may not or need not be informed about the past routing of an incoming downlink communication with data originating from a host computer 3230 to be forwarded (e.g., handed over) to a connected UE 3291. Similarly, the base station 3212 need not be aware of the future routing of an outgoing uplink communication originating from the UE 3291 towards the host computer 3230.

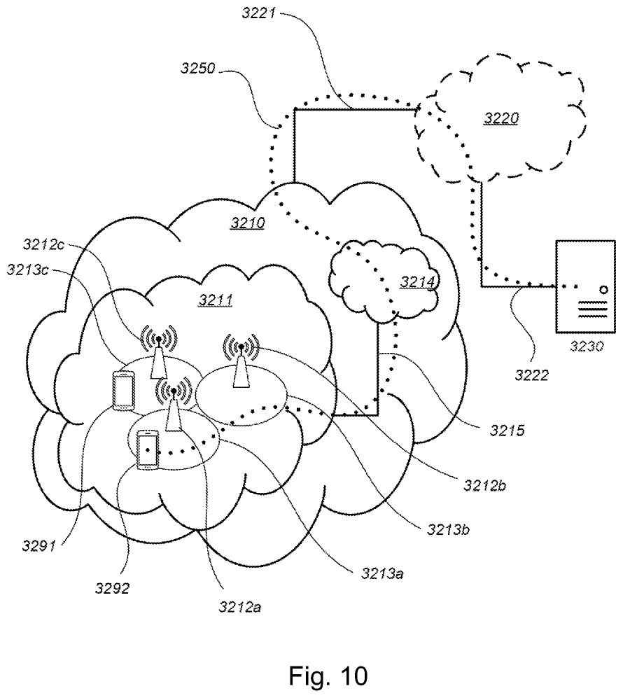

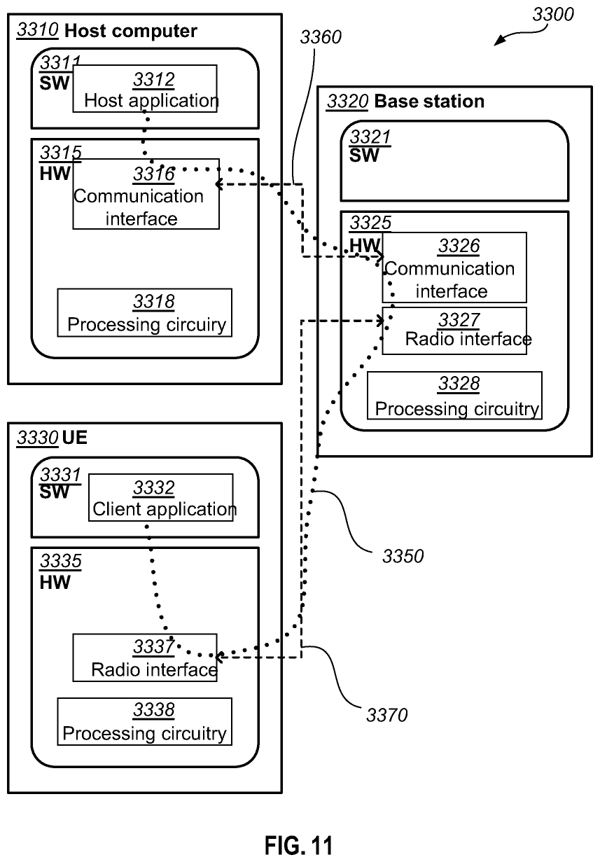

Example implementations, in accordance with an embodiment, of the UE, base station and host computer discussed in the preceding paragraphs will now be described with reference to FIG. 11. In a communication system 3300, a host computer 3310 comprises hardware 3315 including a communication interface 3316 configured to set up and maintain a wired or wireless connection with an interface of a different communication device of the communication system 3300. The host computer 3310 further comprises processing circuitry 3318, which may have storage and/or processing capabilities. In particular, the processing circuitry 3318 may comprise one or more programmable processors, application-specific integrated circuits, field programmable gate arrays or combinations of these (not shown) adapted to execute instructions. The host computer 3310 further comprises software 3311, which is stored in or accessible by the host computer 3310 and executable by the processing circuitry 3318. The software 3311 includes a host application 3312. The host application 3312 may be operable to provide a service to a remote user, such as a UE 3330 connecting via an OTT connection 3350 terminating at the UE 3330 and the host computer 3310. In providing the service to the remote user, the host application 3312 may provide user data which is transmitted using the OTT connection 3350.

The communication system 3300 further includes a base station 3320 provided in a telecommunication system and comprising hardware 3325 enabling it to communicate with the host computer 3310 and with the UE 3330. The hardware 3325 may include a communication interface 3326 for setting up and maintaining a wired or wireless connection with an interface of a different communication device of the communication system 3300, as well as a radio interface 3327 for setting up and maintaining at least a wireless connection 3370 with a UE 3330 located in a coverage area (not shown) served by the base station 3320. The communication interface 3326 may be configured to facilitate a connection 3360 to the host computer 3310. The connection 3360 may be direct or it may pass through a core network (not shown in FIG. 11) of the telecommunication system and/or through one or more intermediate networks outside the telecommunication system. In the embodiment shown, the hardware 3325 of the base station 3320 further includes processing circuitry 3328, which may comprise one or more programmable processors, application-specific integrated circuits, field programmable gate arrays or combinations of these (not shown) adapted to execute instructions. The base station 3320 further has software 3321 stored internally or accessible via an external connection.

The communication system 3300 further includes the UE 3330 already referred to. Its hardware 3335 may include a radio interface 3337 configured to set up and maintain a wireless connection 3370 with a base station serving a coverage area in which the UE 3330 is currently located. The hardware 3335 of the UE 3330 further includes processing circuitry 3338, which may comprise one or more programmable processors, application-specific integrated circuits, field programmable gate arrays or combinations of these (not shown) adapted to execute instructions. The UE 3330 further comprises software 3331, which is stored in or accessible by the UE 3330 and executable by the processing circuitry 3338. The software 3331 includes a client application 3332. The client application 3332 may be operable to provide a service to a human or non-human user via the UE 3330, with the support of the host computer 3310. In the host computer 3310, an executing host application 3312 may communicate with the executing client application 3332 via the OTT connection 3350 terminating at the UE 3330 and the host computer 3310. In providing the service to the user, the client application 3332 may receive request data from the host application 3312 and provide user data in response to the request data. The OTT connection 3350 may transfer both the request data and the user data. The client application 3332 may interact with the user to generate the user data that it provides.

It is noted that the host computer 3310, base station 3320 and UE 3330 illustrated in FIG. 11 may be identical to the host computer 3230, one of the base stations 3212a, 3212b, 3212c and one of the UEs 3291, 3292 of FIG. 10, respectively. This is to say, the inner workings of these entities may be as shown in FIG. 11 and independently, the surrounding network topology may be that of FIG. 10.

In FIG. 11, the OTT connection 3350 has been drawn abstractly to illustrate the communication between the host computer 3310 and the use equipment 3330 via the base station 3320, without explicit reference to any intermediary devices and the precise routing of messages via these devices. Network infrastructure may determine the routing, which it may be configured to hide from the UE 3330 or from the service provider operating the host computer 3310, or both. While the OTT connection 3350 is active, the network infrastructure may further take decisions by which it dynamically changes the routing (e.g., on the basis of load balancing consideration or reconfiguration of the network).

The wireless connection 3370 between the UE 3330 and the base station 3320 is in accordance with the teachings of the embodiments described throughout this disclosure. One or more of the various embodiments improve the performance of OTT services provided to the UE 3330 using the OTT connection 3350, in which the wireless connection 3370 forms the last segment. More precisely, the teachings of these embodiments may improve the applicable RAN effect: data rate, latency, power consumption, reduced interference, and thereby provide benefits such as corresponding effect on the OTT service: e.g. reduced user waiting time, relaxed restriction on file size, better responsiveness, extended battery lifetime.

A measurement procedure may be provided for the purpose of monitoring data rate, latency and other factors on which the one or more embodiments improve. There may further be an optional network functionality for reconfiguring the OTT connection 3350 between the host computer 3310 and UE 3330, in response to variations in the measurement results. The measurement procedure and/or the network functionality for reconfiguring the OTT connection 3350 may be implemented in the software 3311 of the host computer 3310 or in the software 3331 of the UE 3330, or both. In embodiments, sensors (not shown) may be deployed in or in association with communication devices through which the OTT connection 3350 passes; the sensors may participate in the measurement procedure by supplying values of the monitored quantities exemplified above, or supplying values of other physical quantities from which software 3311, 3331 may compute or estimate the monitored quantities. The reconfiguring of the OTT connection 3350 may include message format, retransmission settings, preferred routing etc.; the reconfiguring need not affect the base station 3320, and it may be unknown or imperceptible to the base station 3320. Such procedures and functionalities may be known and practiced in the art. In certain embodiments, measurements may involve proprietary UE signaling facilitating the host computer's 3310 measurements of throughput, propagation times, latency and the like. The measurements may be implemented in that the software 3311, 3331 causes messages to be transmitted, in particular empty or ‘dummy’ messages, using the OTT connection 3350 while it monitors propagation times, errors etc.

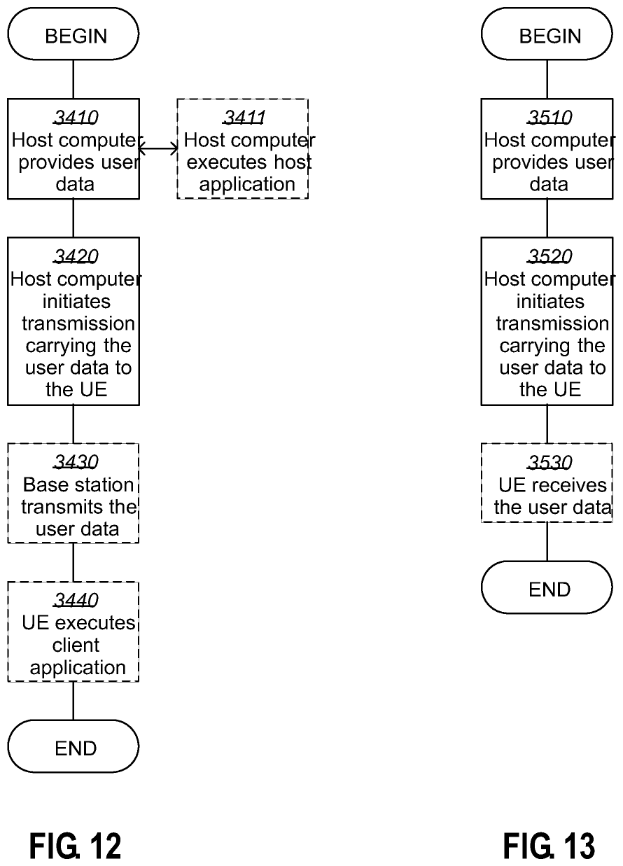

FIG. 12 is a flowchart illustrating a method implemented in a communication system, in accordance with one embodiment. The communication system includes a host computer, a base station such as the network node 112, and a UE such as the wireless device 120, which may be those described with reference to FIG. 10 and FIG. 11. For simplicity of the present disclosure, only drawing references to FIG. 12 will be included in this section. In a first action 3410 of the method, the host computer provides user data. In an optional subaction 3411 of the first action 3410, the host computer provides the user data by executing a host application. In a second action 3420, the host computer initiates a transmission carrying the user data to the UE. In an optional third action 3430, the base station transmits to the UE the user data which was carried in the transmission that the host computer initiated, in accordance with the teachings of the embodiments described throughout this disclosure. In an optional fourth action 3440, the UE executes a client application associated with the host application executed by the host computer.

FIG. 13 is a flowchart illustrating a method implemented in a communication system, in accordance with one embodiment. The communication system includes a host computer, a base station such as an AP STA, and a UE such as a Non-AP STA which may be those described with reference to FIG. 10 and FIG. 11. For simplicity of the present disclosure, only drawing references to FIG. 13 will be included in this section. In a first action 3510 of the method, the host computer provides user data. In an optional subaction (not shown) the host computer provides the user data by executing a host application. In a second action 3520, the host computer initiates a transmission carrying the user data to the UE. The transmission may pass via the base station, in accordance with the teachings of the embodiments described throughout this disclosure. In an optional third action 3530, the UE receives the user data carried in the transmission.

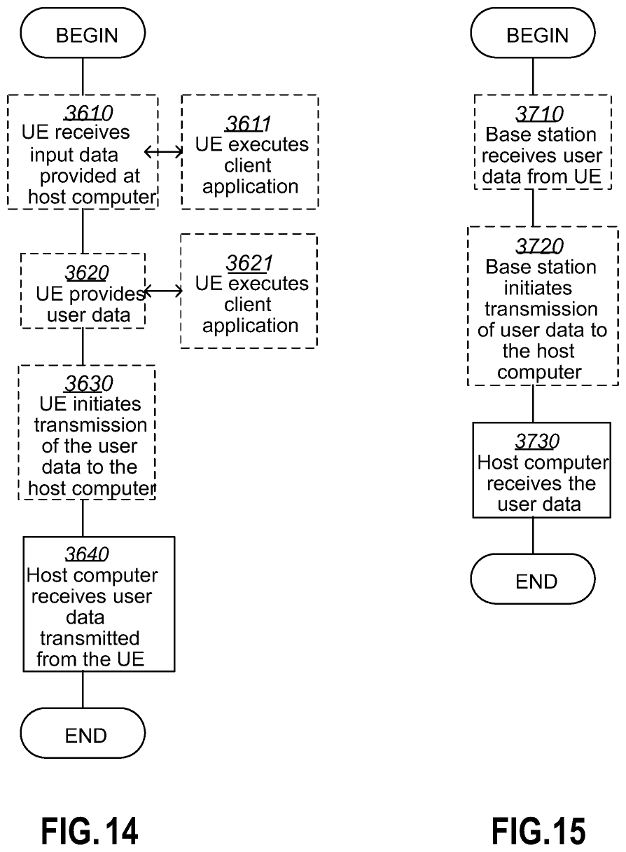

FIG. 14 is a flowchart illustrating a method implemented in a communication system, in accordance with one embodiment. The communication system includes a host computer, a base station such as an AP STA, and a UE such as a Non-AP STA which may be those described with reference to FIG. 10 and FIG. 11. For simplicity of the present disclosure, only drawing references to FIG. 14 will be included in this section. In an optional first action 3610 of the method, the UE receives input data provided by the host computer. Additionally or alternatively, in an optional second action 3620, the UE provides user data. In an optional subaction 3621 of the second action 3620, the UE provides the user data by executing a client application. In a further optional subaction 3611 of the first action 3610, the UE executes a client application which provides the user data in reaction to the received input data provided by the host computer. In providing the user data, the executed client application may further consider user input received from the user. Regardless of the specific manner in which the user data was provided, the UE initiates, in an optional third subaction 3630, transmission of the user data to the host computer. In a fourth action 3640 of the method, the host computer receives the user data transmitted from the UE, in accordance with the teachings of the embodiments described throughout this disclosure.

FIG. 15 is a flowchart illustrating a method implemented in a communication system, in accordance with one embodiment. The communication system includes a host computer, a base station such as an AP STA, and a UE such as a Non-AP STA which may be those described with reference to FIG. 10 and FIG. 11 For simplicity of the present disclosure, only drawing references to FIG. 15 will be included in this section. In an optional first action 3710 of the method, in accordance with the teachings of the embodiments described throughout this disclosure, the base station receives user data from the UE. In an optional second action 3720, the base station initiates transmission of the received user data to the host computer. In a third action 3730, the host computer receives the user data carried in the transmission initiated by the base station.

When using the word “comprise” or “comprising” it shall be interpreted as non-limiting, i.e. meaning “consist at least of”.

The embodiments herein are not limited to the above described preferred embodiments. Various alternatives, modifications and equivalents may be used.

1. A method performed by a first network node for handling communication of data in a wireless communications network, the first network node managing a virtual communication model, the virtual communication model simulating a communication of a set of data streams between a wireless device and a second network node, the set of data streams being associated with a remotely controlled device, the second network node managing a virtual infrastructure model, and the virtual infrastructure model simulating at least part of the remotely controlled device based on the set of data streams, the method comprising:
receiving from the second network node, a relationship indication, wherein the relationship indication indicates at least one relationship between one or more first data streams in the set of data streams and any one or more out of:
one or more second data streams in the set of data streams; and
the virtual infrastructure model; and
based on the relationship indication and the virtual communication model, triggering a reduction of data to be communicated in the set of data streams.

2. The method according to claim 1, wherein triggering the reduction of the data to be communicated in the set of data streams comprises any one or more out of:
instructing a serving network node to trigger the reduction of the data to be communicated in the set of data streams, wherein the wireless device is served in a cell by the serving network node; and
instructing the wireless device to adjust a pre-processing of the data to be communicated in the set of data streams.

3. The method according to claim 2, wherein instructing the serving network node to trigger the reduction of the data to be communicated in the set of data streams comprises any one or more out of:
instructing the serving network node to drop one or more data packets in the set of data streams; and
instructing the serving network node to instruct the wireless device to adjust the pre-processing of the data to be communicated in the set of data streams.

4. The method according to claim 1, further comprising:
based on the at least one relationship and the virtual communication model, determining whether or not it is possible to reduce the data to be communicated in the set of data streams; and
wherein triggering the reduction of data is performed when it is determined to be possible to reduce the data to be communicated in the set of data streams.

5. A method performed by a second network node for handling communication of data in a wireless communications network, a first network node managing a virtual communication model, the virtual communication model simulating a communication of a set of data streams between a wireless device and the second network node, the set of data streams being associated with a remotely controlled device, the second network node managing a virtual infrastructure model, and the virtual infrastructure model simulating at least part of the remotely controlled device based on the set of data streams, the method comprising:
determining at least one relationship between one or more first data streams in the set of data streams and any one or more out of:
one or more second data streams in the set of data streams; and
the virtual infrastructure model; and
transmitting a relationship indication to the first network node, the relationship indication indicating the determined at least one relationship.

6. The method according to claim 5, wherein determining the at least one relationship between the one or more first data streams in the set of data streams and the one or more second data streams in the set of data streams comprises determining that at least part of the data communicated in the one or more first data streams is deducible based on the one or more second data streams.

7. The method according to claim 5, wherein determining the at least one relationship between the one or more first data streams in the set of data streams and the virtual infrastructure model comprises determining a functionality of the virtual infrastructure model based on at least part of the data communicated in the one or more first data streams.

8. A method performed by a wireless device for handling communication of data in a wireless communications network, a first network node managing a virtual communication model, the virtual communication model simulating a communication of a set of data streams between the wireless device and a second network node, the set of data streams being associated with a remotely controlled device, and the second network node managing a virtual infrastructure model, the virtual infrastructure model simulating at least part of the remotely controlled device based on the set of data streams, and the wireless device pre-processing data to be communicated in the set of data streams, the method comprising:
receiving an instruction to adjust the pre-processing of data to be communicated in the set of data streams; and
adjusting the pre-processing of the data to be communicated in the set of data streams based on the received instruction.

9. The method according to claim 8, wherein adjusting the pre-processing of the data to be communicated in the set of data streams comprises reducing the data to be communicated in the set of data streams by any one or more out of:
refraining from communicating one or more data streams in the set of data streams;
refraining from communicating at least one data packet in one or more data streams in the set of data streams; and
adjusting a frequency for communicating data in at least one or more data streams in the set of data streams.

10. A first network node configured to handle communication of data in a wireless communications network, the first network node is being further configured to manage a virtual communication model, the virtual communication model simulating a communication of a set of data streams between a wireless device and a second network node, the set of data streams being associated with a remotely controlled device, the second network node managing a virtual infrastructure model, and the virtual infrastructure model simulating at least part of the remotely controlled device based on the set of data streams, the first network node is further configured to:
receive from the second network node, a relationship indication, wherein the relationship indication indicates at least one relationship between one or more first data streams in the set of data streams and any one or more out of:
one or more second data streams in the set of data streams; and
the virtual infrastructure model; and
based on the relationship indication and the virtual communication model, trigger a reduction of data to be communicated in the set of data streams.

11. The first network node according to claim 10, further configured to trigger the reduction of the data to be communicated in the set of data streams by any one or more out of:
instructing a serving network node to trigger the reduction of the data to be communicated in the set of data streams, wherein the wireless device is served in a cell by the serving network node; and
instructing the wireless device to adjust a pre-processing of the data to be communicated in the set of data streams.

12. The first network node according to claim 11, further configured to instruct the serving network node to trigger the reduction of the data to be communicated in the set of data streams by any one or more out of:
instructing the serving network node to drop one or more data packets in the set of data streams; and
instructing the serving network node to instruct the wireless device to adjust the pre-processing of the data to be communicated in the set of data streams.

13. The first network node according to claim 11, further configured to:
based on the at least one relationship and the virtual communication model; determine whether or not it is possible to reduce the data to be communicated in the set of data streams; and
trigger the reduction of data when it is determined to be possible to reduce the data to be communicated in the set of data streams.

14. A second network node configured to handle communication of data in a wireless communications network, wherein a first network node managing a virtual communication model, wherein the virtual communication model simulating a communication of a set of data streams between a wireless device and the second network node, the set of data streams being associated with a remotely controlled device, the second network node is being configured to manage a virtual infrastructure model, and the virtual infrastructure model simulating at least part of the remotely controlled device based on the set of data streams, the second network node is further configured to:
determine at least one relationship between one or more first data streams in the set of data streams and any one or more out of:
one or more second data streams in the set of data streams; and
the virtual infrastructure model;
transmit a relationship indication to the first network node, wherein the relationship indication indicates the determined at least one relationship.

15. The second network node according to claim 14, further configured to determine the at least one relationship between the one or more first data streams in the set of data streams and the one or more second data streams in the set of data streams comprises determining that at least part of the data communicated in the one or more first data streams is deducible based on the one or more second data streams.

16. The second network node according to claim 14, further configured to determine the at least one relationship between the one or more first data streams in the set of data streams and the virtual infrastructure model by determining a functionality of the virtual infrastructure model based on at least part of the data communicated in the one or more first data streams.

17. A wireless device configured to handle communication of data in a wireless communications network, a first network node managing a virtual communication model, the virtual communication model simulating a communication of a set of data streams between the wireless device and a second network node, the set of data streams being associated with a remotely controlled device, and the second network node managing a virtual infrastructure model, the virtual infrastructure model simulating at least part of the remotely controlled device based on the set of data streams, and the wireless device is configured to pre-process data to be communicated in the set of data streams, the wireless device is further configured to:
receive an instruction to adjust a pre-processing of data to be communicated in the set of data streams; and
adjust the pre-processing of the data to be communicated in the set of data streams based on the received instruction.

18. The wireless device according to claim 17, further configured to adjust the pre-processing of the data to be communicated in the set of data streams by reducing the data to be communicated in the set of data streams by any one or more out of:
refraining from communicating one or more data streams in the set of data streams;
refraining from communicating at least one data packet in one or more data streams in the set of data streams; and
adjusting a frequency for communicating data in at least one or more data streams in the set of data streams.

19.-24. (canceled)

25. The method according to claim 2, further comprising:
based on the at least one relationship and the virtual communication model, determining whether or not it is possible to reduce the data to be communicated in the set of data streams; and
wherein triggering the reduction of data is performed when it is determined to be possible to reduce the data to be communicated in the set of data streams.

26. The method according to claim 3, further comprising:
based on the at least one relationship and the virtual communication model, determining whether or not it is possible to reduce the data to be communicated in the set of data streams; and
wherein triggering the reduction of data is performed when it is determined to be possible to reduce the data to be communicated in the set of data streams.
